(19) United States
(12) Patent Application Publication
(10) Pub. No.: US 2007/0095510 A1
(43) Pub. Date: May 3, 2007

(54) HEAT-PIPE TYPE HEAT SINK

(75) Inventors: YEU-LIH LIN, Tu-Cheng,Taipei Hsien (TW); Ai-Min Huang, Shenzhen (CN); Jun Luo, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,184

(22) Filed: Jul. 7, 2006

(30) Foreign Application Priority Data
Nov. 3, 2005 (CN) 200510100953.6

(51) Int. Cl. H05K 7/20

(52) U.S. Cl. 165/104.33; 165/80.3; 361/700

(57) ABSTRACT

A heat-pipe type heat sink (10) includes a plurality of fins (140) each defining at least a through hole (143) therein, at least a heat pipe (16) extending through the through holes of the fins, and soldering material filled in spaces formed between the heat pipe and the fins. A sidewall of the through hole forms a first fringe (145) contacting with the heat pipe, and a second fringe (146) smoothly and linearly connecting with the first fringe. The second fringe includes two guide portions (147), which are capable of guiding the molten soldering material to flow towards the first fringe to fill in the spaces to bond the heat pipe to the fins after the molten soldering material is cooled. The through hole has a teardrop-like shape.

### FIELD OF THE INVENTION

The present invention relates generally to a heat sink, and more particularly to a heat-pipe type heat sink for dissipating heat generated by electronic components.

### DESCRIPTION OF RELATED ART

Referring to U.S. Pat. No. 6,435,266, a conventional heat-pipe type heat sink is shown. The heat sink includes a plurality of fins and a heat pipe extending through the fins. Each of the fins defines a larger hole, and a smaller hole above the larger hole. The smaller hole partially connects with the larger hole at a bottom end thereof. Two projections are formed at the joint of the smaller and the larger holes and extend towards each other, thereby forming a neck portion at that joint.

In assembly of the heat sink, the heat pipe extends through the larger holes of the fins, while a solder stick extends through the smaller holes of the fins. The solder stick is heated to a melting point so that the molten solder flows into the larger holes and fills in clearances formed between the heat pipe and the fins. The molten solder is cooled so as to firmly bond the heat pipe to the fins to complete the assembly of the heat sink.

In the assembly of the heat sink, a part of the molten solder sticks to the projections of the neck portions of the fins, when the molten solder flows towards the larger holes. When that part of the molten solder is cooled, a plurality of solder beads is formed at the projections of the neck portions of the fins. These solder beads do not have any help regarding the thermal connection of the heat pipe and the fins. Furthermore, they adversely affect the aesthetic appearance of the heat sink. The projections hinder the molten solder from smoothly and fully flowing into the larger holes. This results in a possible incomplete connection between the heat pipe and the fins. Thus, an improvement is required to overcome the defects of the prior art.

### SUMMARY OF THE INVENTION

The present invention relates to a heat-pipe type heat sink for dissipating heat generated by electronic components. According to a preferred embodiment of the present invention, the heat-pipe type heat sink includes a plurality of fins each defining at least a through hole therein, at least a heat pipe extending through the through holes of the fins, and soldering material filled in spaces formed between the heat pipe and the fins. Sidewall of the through hole forms a first fringe contacting with the heat pipe, and a second fringe smoothly connecting with the first fringe. The second fringe includes two guide portions, which are capable of guiding the molten soldering material flowing towards the first fringe to fill in the spaces to bond the heat pipe to the fins after the molten soldering material is cooled. The through hole has a shape of a teardrop.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is an exploded, isometric view of a heat-pipe type heat sink according to a preferred embodiment of the present invention;

FIG. 2 is an assembled view of the heat-pipe type heat sink of FIG. 1;

FIG. 3 is a cross sectional view of the heat-pipe type heat sink of FIG. 2, taken along line III-III thereof; and

FIG. 4 is an isometric view of a fin of the heat-pipe type heat sink of FIG. 1.

### DETAILED DESCRIPTION OF THE INVENTION

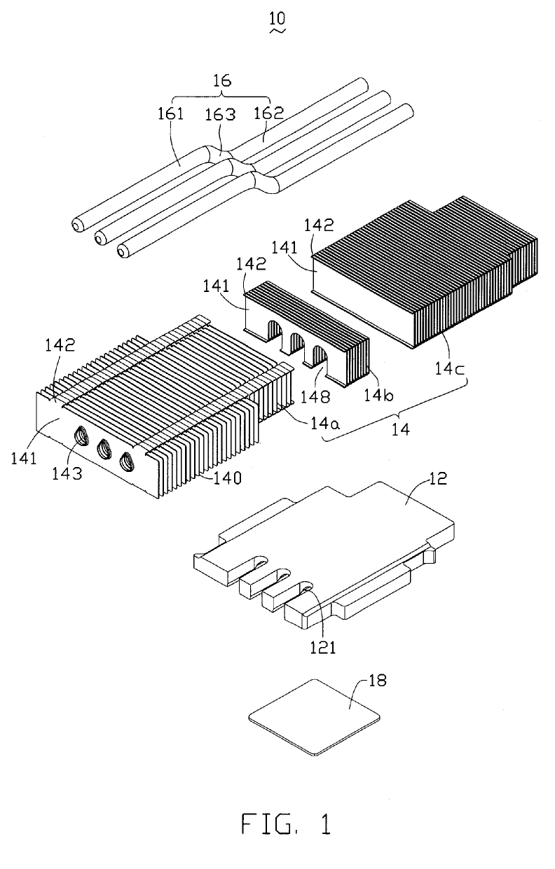

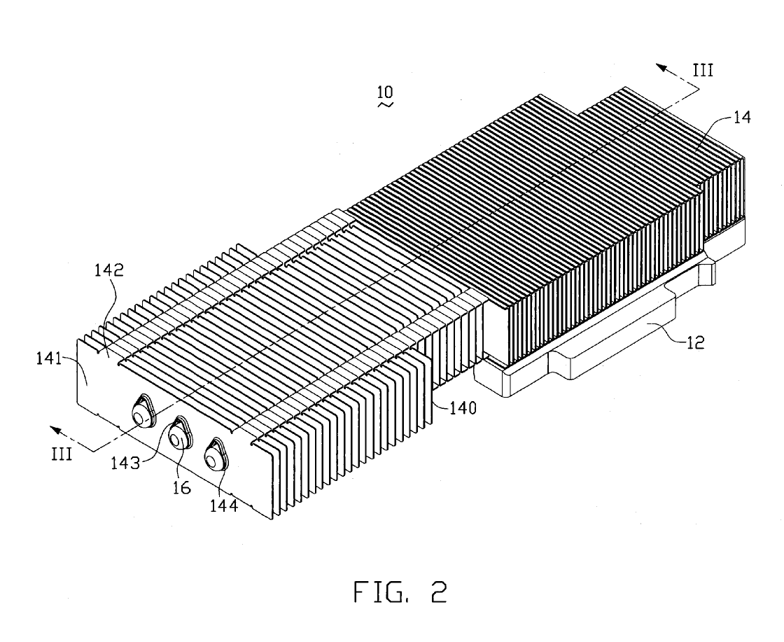

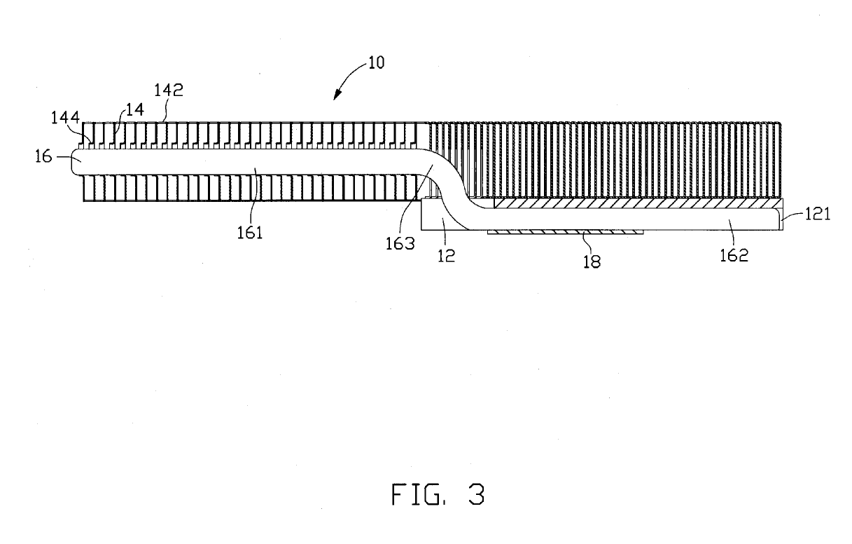

Referring to FIGS. 1 through 3, a heat-pipe type heat sink 10 according to a preferred embodiment of the present invention is shown. The heat-pipe type heat sink 10 includes a base 12, a fin assembly 14 disposed on the base 12, and three heat pipes 16 extending through the fin assembly 14. Each of the heat pipes 16 includes a linear-shaped evaporator section 162, a condenser section 161 parallel to the evaporator section 162, and an arc-shaped adiabatic section 163 integrally connected with the evaporator and condenser sections 162, 161. The evaporator and condenser sections 162, 161 of the heat pipe 16 respectively contact with a heat-generating electronic component 18 and the fin assembly 14 for transferring heat therebetween.

The fin assembly 14 includes a plurality of parallel fins 140, and is divided into three portions, i.e. a first portion 14a, a second portion 14b, and a third portion 14c. Each fin 140 of the first portion 14a of the fin assembly 14 includes a rectangular-shaped main body 141, and four flanges 142 extending backwardly from upper and bottom sides of the main body 141. The fins 140 of the first portion 14a of the fin assembly 14 are stacked together with the flanges 142 of a front fin 140 abutting against the main body 141 of a rear fin 140. Each fin 140 of the second and third portions 14b, 14c of the fin assembly 14 includes a rectangular-shaped main body 141, and two flanges 142 extending forwardly from upper and bottom sides of the main body 141. The fins 140 of the second and third portions 14b, 14c of the fin assembly 14 are stacked together with the flanges 142 of a rear fin 140 abutting against the main body 141 of a front fin 140. A plurality of air passages are formed between two adjacent fins 140, allowing the airflow to pass therethrough. The main body 141 of each fin 140 of the first portion 14a of the fin assembly 14 defines three through holes 143 therein, allowing the condenser sections 161 of the heat pipes 16 extending therethrough. Three collars 144 extend forwardly from peripheries of the through holes 143, contacting with the condenser sections 161 of the heat pipes 16. The main body 141 of each fin 140 of the second portion 14b of the fin assembly 14 defines three U-shaped slots 148 in a bottom thereof, for allowing the adiabatic sections 163 of the heat pipes 16 extending therethrough. A bottom portion of the base 12 defines three parallel grooves 121 therein, for receiving the evaporator sections 162 of the heat pipes 16 therein. The heat-generating electronic component 18 is mounted to the bottom surface of the base 12 and directly contacting with the evaporator sections 162 of the heat pipes 16. Alternatively, there may be a heat absorbing plate sandwiched between the evaporator sections 162 of the heat pipes 16 and the heat-generating electronic component 18 to transfer heat therebetween.

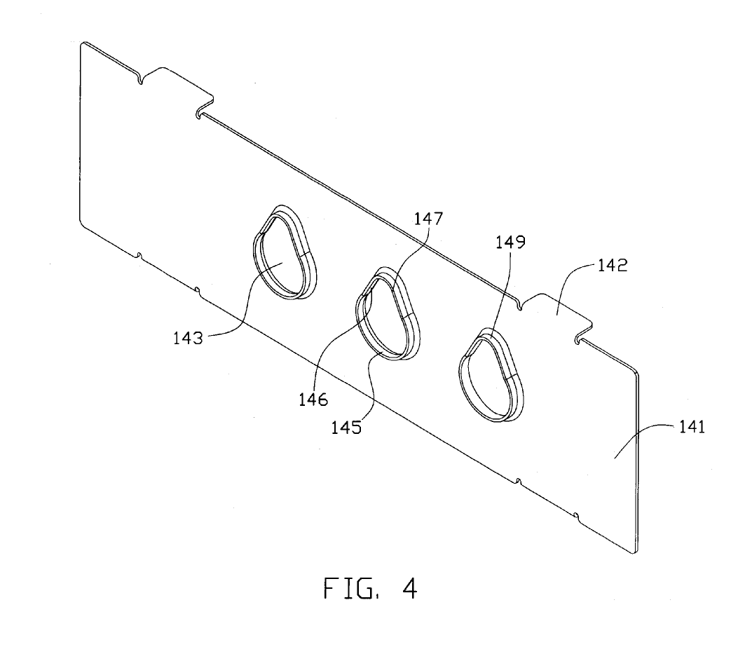

Particularly referring to FIG. 4, each through hole 143 has a general shape of a teardrop. The collar 144 of each through hole 143 includes an arcuate first inner fringe 145 mated with the condenser section 161 of the heat pipe 16, and a V-shaped second inner fringe 146 above the first inner fringe 145. Soldering material (not shown) such as solder paste, or solder bar is filled in a space enclosed by the second inner fringe 146. The second inner fringe 146 includes two slantwise guiding portions 147 smoothly and linearly connected with top ends of the first inner fringe 145. The distance between the guiding portions 147 of the second inner fringe 146 is gradually increased from a top portion of the collar 144 towards the top ends of the first inner fringe 145. The collar 144 is substantially teardrop-shaped in profile and has no projection extending from its inner fringes 145, 146 inwardly. The guiding portions 147 of the second inner fringe 146 guide the molten soldering material entirely and smoothly from the top portion of the collar 144 towards the first inner fringe 145 to fill in a clearance between the condenser section 161 of the heat pipe 16 and the first inner fringe 145.

In assembly of the heat-pipe type heat sink 10, the fins 140 of the fin assembly 14 are stacked together. The evaporator, the condenser, and the adiabatic sections 162, 161, 163 of the heat pipes 16 are respectively received in the grooves 121 of the base 12, the through holes 143 of the first portion 14a of the fin assembly 14, and the slots 148 of the second portion 14b of the fin assembly 14. The soldering material is disposed in the spaces enclosed by the guiding portions 147 of the second inner fringes 146 and above the condenser sections 161 of the heat pipes 16. The heat-pipe type heat sink 10 is thus preassembled. The preassembled heat-pipe type heat sink 10 is heated to a melting point of the soldering material, so that the molten soldering material is guided by the guiding portions 147 of the second inner fringes 146 towards the first inner fringes 145 and fills in clearances formed between the first inner fringes 145 and the condenser sections 161 of the heat pipes 16. The molten soldering material is cooled so as to firmly bond the condenser sections 161 of the heat pipes 16 to the first inner fringes 145 of the fin assembly 14. The assembly of the heat sink 10 is thus completed.

In the present invention, the collar 144 is teardrop-shaped in profile and has no projection extending inwardly from its inner fringes 145, 146. Such projection could form a barrier preventing the molten soldering material from smoothly and entirely flowing downwards and could have solder beads formed thereon, as explained in connection with the prior art. The present invention overcomes such problems. In addition, a part of the soldering material can spread on the collars 144 of the fins 140 of the first portion 14a of the fin assembly 14 and bond the condenser sections 161 of the heat pipes 16 thereat to the fins 140, which increases contacting areas between the condenser sections 161 of the heat pipes 16 and the fins 140 of the first portion 14a of the fin assembly 14, and further improves heat dissipation efficiency of the heat-pipe type heat sink 10.

Particularly referring to FIG. 4, the guiding portions 147 of the second inner fringe 146 connect with each other at a top end of the collar 144 via an arcuate tip portion 149. Alternatively, the tip portion 149 may not be arcuate, but is sharp.

In the preferred embodiment of the present invention, the second inner fringe 146 is disposed above the first inner fringe 145. Alternatively, the second inner fringe may be disposed below the first inner fringe, or on the right or the left side of the first inner fringe. In the assembly of the heat sink with such configurations, during heating thereof, the heat-pipe type heat sink needs to be rotated to a position, where the molten soldering material can be guided by gravity and the guiding portions towards the first inner fringes and evenly distributed around the condenser sections of the heat pipes. The cross section of the condenser section of the heat pipe is round-shaped in this embodiment. Alternatively, the cross section of the condenser section of the heat pipe may have any other appropriate configuration, whilst the first fringe may have a corresponding configuration mated with the condenser section of the heat pipe.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat-pipe type heat sink comprising:
a plurality of fins each defining a through hole therein;
a heat pipe extending through the through holes of the fins; and
soldering material filled in the through holes between the heat pipe and the fins;
wherein a sidewall of the through hole forms a first fringe contacting with the heat pipe, and a second fringe connecting with the first fringe, the second fringe comprises a tip portion distant from the first fringe and two guiding portions extending from the tip portion toward the first fringe, a distance between the two guiding portions is gradually increased along a direction from the tip portion toward the first fringe, and the guide portions are capable of guiding the soldering material in molten state to flow towards the first fringe to fill in a space between the heat pipe and each of the fins to bond the heat pipe and the fins together after the molten soldering material is cooled.

2. The heat-pipe type heat sink as described in claim 1, wherein the second fringe is V-shaped in profile.

3. The heat-pipe type heat sink as described in claim 1, wherein the first fringe is arcuate in profile.

4. The heat-pipe type heat sink as described in claim 1, wherein the through hole has a teardrop-shape in profile.

5. The heat-pipe type heat sink as described in claim 1, wherein each fin extends at least a collar from the first fringe of the through hole for contacting with the heat pipe.

6. The heat-pipe type heat sink as described in claim 1, wherein the heat pipe comprises an evaporator section, a condenser section parallel to the evaporator section, and an adiabatic section integrally connecting the evaporator section with the condenser section, the condenser section of the heat pipe is received in the through holes of the fins, whilst the adiabatic section is received in slots defined in parts of the fins.

7. The heat-pipe type heat sink as described in claim 6, further comprising a base thermally contacting with an electronic component, the base defining at least a groove therein for receiving the evaporator section of the heat pipe therein.

8. A heat-pipe type heat sink configured for dissipating heat for an electronic component comprising:
a fin assembly comprising a plurality of fins, at least one portion of the fins defining a through hole therein;
a heat pipe extending through the through holes; and
a soldering material filled in the through holes between the heat pipe and the fins;
wherein a sidewall of the through hole forms a first fringe contacting with a condenser section of the heat pipe, and a second fringe smoothly connecting with the first fringe, the second fringe comprises two guiding portions, and a distance between the guiding portions of the second fringe is gradually increased from a top portion of the through hole towards the first fringe.

9. The heat-pipe type heat sink as described in claim 8, wherein the second fringe has a V-shaped profile.

10. The heat-pipe type heat sink as described in claim 8, wherein the first fringe has an arcuate profile mated with the condenser section of the heat pipe.

11. The heat-pipe type heat sink as described in claim 8, wherein the guiding portions of the second fringe smoothly and linearly connect with the first fringe.

12. The heat-pipe type heat sink as described in claim 8, wherein each fin extends at least a collar from the first fringe of the through hole for contacting with the condenser section of the heat pipe.

13. The heat-pipe type heat sink as described in claim 8, wherein another portion of the fins defines at least a slot therein for receiving an adiabatic section of the heat pipe therein.

14. The heat-pipe type heat sink as described in claim 8, further comprising a base contacting with the electronic component, the base defining at least a groove therein for receiving an evaporator section of the heat pipe therein.

15. A heat sink comprising:
a fin defining a substantially teardrop-shaped through hole therein, the teardrop-shaped through hole having a large part and a small part;
a heat pipe having a condenser section and an evaporator section adapted for thermally connecting with a heat generating electronic component, wherein the condenser section is received in the large part of the teardrop-shaped through hole; and
soldering material filled in a clearance between the condenser section of the heat pipe and the fin so that the fin and the condenser section of the heat pipe are thermally and mechanically connected together.

16. The heat sink as described in claim 15, wherein the fin has a collar formed around at least the large part of the teardrop-shaped through hole, the soldering material also filling in a clearance between the condenser section of the heat pipe and the collar so that the collar and the condenser section of the heat pipe are thermally and mechanically connected together.

17. The heat sink as described in claim 16, wherein the collar is formed around the teardrop-shaped through hole entirely.
